(19) United States
(12) Patent Application Publication
(10) Pub. No.: US 2015/0221677 A1
(43) Pub. Date: Aug. 6, 2015

(54) ACTIVE MATRIX SUBSTRATE, DISPLAY DEVICE, AND PRODUCTION METHOD THEREFOR

(71) Applicant: Sharp Kabushiki Kaisha, Osaka-shi, Osaka (JP)

(72) Inventors: Tohru Okabe, Osaka-shi (JP); Hirohiko Nishiki, Osaka-shi (JP); Takeshi Hara, Osaka-shi (JP); Kenichi Kitoh, Osaka-shi (JP); Hisao Ochi, Osaka-shi (JP)

(21) Appl. No.: 14/425,690

(22) PCT Filed: Sep. 17, 2013
(86) PCT No.: PCT/JP2013/074963

§ 371 Date: Mar. 4, 2015

(30) Foreign Application Priority Data
Sep. 24, 2012 (JP) 2012-210086

(51) Int. Cl. H01L 27/12; H01L 29/786; H01L 21/441; H01L 29/66; H01L 21/02; G02F 1/1368; H01L 29/24

(52) U.S. Cl. CPC H01L 27/1225; G02F 1/1368; H01L 29/7869; H01L 29/78606; H01L 29/24; H01L 27/1259; H01L 29/66969; H01L 27/1248; H01L 21/02565; H01L 21/441

(57) ABSTRACT

The present invention provides an active matrix substrate including a thin film transistor that sufficiently achieves high reliability and a low capacitance, a production method for the active matrix substrate without an increase in the number of photomasks, a display device including the active matrix substrate, and a production method for the display device. The active matrix substrate of the present invention includes a thin film transistor that includes a semiconductor layer consisting of an oxide semiconductor. The active matrix substrate includes at least the semiconductor layer consisting of the oxide semiconductor, an etching stopper layer, and an interlayer insulating film formed from a spin-on-glass material. In the plan view of the principal surface of the substrate, the etching stopper layer covers at least part of the semiconductor layer, and the interlayer insulating film covers at least part of the etching stopper layer.

### TECHNICAL FIELD

The present invention relates to an active matrix substrate, a display device, and production methods therefor. The present invention specifically relates to an active matrix substrate which includes a thin film transistor and which is used as a component in electronic apparatuses such as display devices; a display device; and production methods therefor.

### BACKGROUND ART

Active matrix substrates including elements such as a thin film transistor (hereinafter, also referred to as a TFT) are widely used as components in electronic apparatuses such as liquid crystal display devices, organic electroluminescent display devices, and solar cells.

For example, the active matrix substrate typically includes a circuit structure including m×n matrix wiring (wherein m represents the number of scanning lines (hereinafter, also referred to as gate lines) and n represents the number of signal lines (hereinafter, also referred to as source lines)) and TFTs which serve as switching elements at the intersection points of the scanning and signal lines. The drain lines of the TFTs are connected with pixel electrodes. The peripheral circuits such as scanning driver ICs and data driver ICs are connected with the gate lines and the source lines of the active matrix substrate, respectively.

The circuit of the active matrix substrate is affected by the performance of the TFTs disposed on the active matrix substrate. The performance of the TFTs disposed on the active matrix substrate depends on the material thereof, and thus the material type of the TFTs disposed on the circuit of the active matrix substrate may lead to problems such as failure in driving of the circuit, an inappropriately large circuit size, and a decrease in the yield. Conventional active matrix substrates use a-Si (amorphous silicon) as the material of a semiconductor layer because this material enables inexpensive, easy formation of TFTs on a large glass substrate. Still, a-Si as the material of a semiconductor layer causes a poor electron mobility, making it difficult to produce a large circuit configured to drive rapidly.

Examples of other material of a semiconductor layer of the TFTs include oxide semiconductors.

The following will provide examples of TFTs that include a semiconductor layer consisting of an oxide semiconductor.

One example disclosed is a thin film transistor including a substrate; a gate electrode disposed on the substrate; an active layer which is insulated from the gate electrode by a gate insulating layer and which consists of an oxide semiconductor; a source electrode and a drain electrode coupled with the active layer; and an interface-stabilizing layer disposed on at least one of the upper and lower surfaces of the active layer, wherein the interface-stabilizing layer consists of an oxide having a band gap of 3.0 to 8.0 eV (for example, see Patent Literature 1).

Another example disclosed is a production method for a thin film transistor substrate including the steps of: forming a gate electrode of a thin film transistor and a first electrode of a capacitor on an insulation substrate; forming a gate insulator so as to cover the gate electrode and the first electrode; forming a semiconductor layer consisting of an oxide semiconductor at the positions corresponding to the gate electrode and the first electrode on the gate insulator; forming a source electrode and a drain electrode of the thin film transistor so as to be in contact with the semiconductor layer formed at the position corresponding to the gate electrode; forming a passivation layer so as to cover the thin film transistor; and forming a pixel electrode which is to be electrically connected with the semiconductor layer formed at the position corresponding to the first electrode and the drain electrode and which is to serve as a second electrode of the capacitance. The production method further includes a treatment of lowering the resistance of the semiconductor layer formed at the position corresponding to the gate electrode at any stage in the series of the steps (for example, see Patent Literature 2).

### CITATION LIST

### Patent Literature

### Patent Literature 1: JP 2010-16348 A

### Patent Literature 2: JP 2010-243594 A

### SUMMARY OF INVENTION

### Technical Problem

The TFT that includes a semiconductor layer consisting of an oxide semiconductor can have a higher electron mobility than the TFT that includes a semiconductor layer consisting of a-Si. Still, for example, such a TFT is characteristically vulnerable to hydrogen (H) in silicon nitride (SiNx) that constitutes the passivation film covering the TFT. Specifically, the hydrogen (H) in SiNx (silicon nitride) constituting the passivation film moves to the oxide semiconductor and combines with oxygen (O) in the oxide semiconductor to form water (H₂O), and this water leaves the oxide semiconductor. At this time, the oxygen (O) also leaves the oxide semiconductor, causing oxygen loss in the oxide semiconductor. This leads to a reliability issue of the conversion of the oxide semiconductor into a conductor (for example, in FIG. 3, hydrogen (H) in a passivation film 222 moves to an oxide semiconductor 217 and combines with oxygen (O) in the oxide semiconductor 217, causing oxygen loss in the oxide semiconductor 217 and the resulting conversion of the oxide semiconductor 217 into a conductor).

Production of large, high-definition liquid crystal panels involves problems relating to not only the aforementioned high electron mobility but also reduction in the capacitance between wires (for example, the capacitance between a gate line and a source line). These problems may be solved to some extent by, for example, a method of forming an interlayer insulating film (for example, in FIG. 3, an interlayer insulating film 219 is disposed to suppress the capacitive coupling between wires; in FIG. 5, an interlayer insulating film 419 is disposed to suppress the capacitive coupling between wires). However, such a method includes an additional step using an exposure mask (hereinafter, also referred to as a photomask) for forming the interlayer insulating film. Thus, further improvement is demanded so as to solve the above problems, including the problem relating to further reduction in the capacitance between wires.

Patent Literature 1 discloses a thin film transistor whose active layer can have improved interface characteristics, a production method therefor, and a flat display device including the thin film transistor. The invention of Patent Literature 1, however, fails to solve simultaneously the above problems relating to the conversion of an oxide semiconductor into a conductor due to hydrogen (H) in the passivation film covering a TFT and the reduction in the capacitance between wires. Therefore, further improvement is demanded so as to solve these problems.

Patent Literature 2 discloses a production method for a thin film transistor substrate including a treatment of reducing the resistance of a semiconductor layer that constitutes a capacitor, thereby not only converting the semiconductor layer into a conductor and increasing the capacitance formed on the substrate, but also preventing a capacitance change. The invention of Patent Literature 2, however, fails to solve simultaneously the above problems relating to the conversion of an oxide semiconductor into a conductor due to hydrogen (H) in the passivation film covering a TFT and the reduction in the capacitance between wires.

The present invention is devised in the above situation and aims to provide an active matrix substrate including a thin film transistor which sufficiently achieves high reliability and a low capacitance; a production method for an active matrix substrate including a thin film transistor which sufficiently achieves high reliability and a low capacitance without an increase in the number of photomasks; a display device including an active matrix substrate that includes a thin film transistor which sufficiently achieves high reliability and a low capacitance; and a production method for the display device.

### Solution to Problem

The present inventors have performed various studies on an active matrix substrate including a thin film transistor which sufficiently achieves high reliability and a low capacitance, and focused on a favorable structure of the active matrix substrate. Then, they have found out an active matrix substrate including a thin film transistor that includes a semiconductor layer consisting of an oxide semiconductor, the active matrix substrate including: a glass substrate; a gate electrode and an auxiliary capacitance electrode each disposed on the glass substrate; a gate insulator covering the gate electrode and the auxiliary capacitance electrode; the semiconductor layer consisting of the oxide semiconductor, the semiconductor layer including, on the gate insulator, a portion overlapping at least part of the gate electrode and a portion overlapping at least part of the auxiliary capacitance electrode; an etching stopper layer; an interlayer insulating film formed from a spin-on-glass material; a source electrode and a drain electrode of the thin film transistor, the source and drain electrodes each being in contact with at least part of the semiconductor layer; and a passivation film covering the thin film transistor, the etching stopper layer covering at least part of the semiconductor layer in the plan view of the principal surface of the substrate, and the interlayer insulating film covering at least part of the etching stopper layer in the plan view of the principal surface of the substrate. As a result, the present inventors have arrived at the fact that such an active matrix substrate can solve the aforementioned problems and completed the present invention.

One aspect of the present invention may be an active matrix substrate including a thin film transistor that includes a semiconductor layer consisting of an oxide semiconductor, the active matrix substrate including: a glass substrate; a gate electrode and an auxiliary capacitance electrode each disposed on the glass substrate; a gate insulator covering the gate electrode and the auxiliary capacitance electrode; the semiconductor layer consisting of the oxide semiconductor, the semiconductor layer including, on the gate insulator, a portion overlapping at least part of the gate electrode and a portion overlapping at least part of the auxiliary capacitance electrode; an etching stopper layer; an interlayer insulating film formed from a spin-on-glass material; a source electrode and a drain electrode of the thin film transistor, the source and drain electrodes each being in contact with at least part of the semiconductor layer; and a passivation film covering the thin film transistor, the etching stopper layer covering at least part of the semiconductor layer in the plan view of the principal surface of the substrate, and the interlayer insulating film covering at least part of the etching stopper layer in the plan view of the principal surface of the substrate.

Another aspect of the present invention may be a display device including the active matrix substrate, a substrate facing the active matrix substrate, and a display element interposed between the substrates.

The active matrix substrate of the present invention is not especially limited by other components as long as it essentially includes these components.

The display device of the present invention is not especially limited by other components as long as it essentially includes these components.

The present inventors have also performed various studies on a production method for an active matrix substrate including a thin film transistor which sufficiently achieves high reliability and a low capacitance without an increase in the number of photomasks, and focused on the production method for an active matrix substrate including a favorable structure. Then, they have found out a production method for an active matrix substrate including a thin film transistor that includes a semiconductor layer consisting of an oxide semiconductor, the production method including the steps of: forming a gate electrode and an auxiliary capacitance electrode on a glass substrate; forming a gate insulator so as to cover the gate electrode and the auxiliary capacitance electrode; forming the semiconductor layer that consists of the oxide semiconductor, on the gate insulator, so as to overlap at least part of the gate electrode and at least part of the auxiliary capacitance electrode; depositing an insulation material and a spin-on-glass material; forming an etching stopper layer formed from the insulation material and an interlayer insulating formed film from the spin-on-glass material by patterning the insulation material and the spin-on-glass material; forming a source electrode and a drain electrode of the thin film transistor so as to be in contact with at least part of the semiconductor layer; and forming a passivation film so as to cover the thin film transistor, in the step of forming the etching stopper layer and the interlayer insulating film, the etching stopper layer being formed so as to cover at least part of the surface of the semiconductor layer opposite to the substrate in the plan view of the principal surface of the substrate, and the interlayer insulating film being formed so as to cover at least part of the surface of the etching stopper layer opposite to the substrate in the plan view of the principal surface of the substrate. As a result, the inventors have arrived at the fact that the above method can solve the aforementioned problems and completed the present invention.

Specifically, one aspect of the present invention may be a production method for an active matrix substrate including a thin film transistor that includes a semiconductor layer consisting of an oxide semiconductor, the production method including the steps of: forming a gate electrode and an auxiliary capacitance electrode on a glass substrate; forming a gate insulator so as to cover the gate electrode and the auxiliary capacitance electrode; forming the semiconductor layer that consists of the oxide semiconductor, on the gate insulator, so as to overlap at least part of the gate electrode and at least part of the auxiliary capacitance electrode; depositing an insulation material and a spin-on-glass material; forming an etching stopper layer formed from the insulation material and an interlayer insulating film formed from the spin-on-glass material by patterning the insulation material and the spin-on-glass material; forming a source electrode and a drain electrode of the thin film transistor so as to be in contact with at least part of the semiconductor layer; and forming a passivation film so as to cover the thin film transistor, in the step of forming the etching stopper layer and the interlayer insulating film, the etching stopper layer being formed so as to cover at least part of the surface of the semiconductor layer opposite to the substrate in the plan view of the principal surface of the substrate, and the interlayer insulating film being formed so as to cover at least part of the surface of the etching stopper layer opposite to the substrate in the plan view of the principal surface of the substrate.

Another aspect of the present invention may be a production method for a display device including: producing an active matrix substrate by the production method for an active matrix substrate; and interposing a display element between the active matrix substrate and a substrate facing the active matrix substrate.

The production method for the active matrix substrate of the present invention is not especially limited by other steps as long as these steps are essentially included.

The production method for the display device of the present invention is not especially limited by other steps as long as these steps are essentially included.

### Advantageous Effects of Invention

The respective aspects of the present invention can provide an active matrix substrate including a thin film transistor which sufficiently achieves high reliability and a low capacitance; a production method for an active matrix substrate including a thin film transistor which sufficiently achieves high reliability and a low capacitance without an increase in the number of photomasks; a display device including an active matrix substrate that includes a thin film transistor which sufficiently achieves high reliability and a low capacitance; and a production method for the display device.

### BRIEF DESCRIPTION OF THE DRAWINGS

FIG. 1 is a schematic cross-sectional view of an active matrix substrate of Embodiment 1.

FIG. 2 is a process chart showing a production process of a TFT and an auxiliary capacitance part of the active matrix substrate of Embodiment 1.

FIG. 3 is a schematic cross-sectional view of a conventional active matrix substrate of Comparative Embodiment 1.

FIG. 4 is a process chart showing a production process of a TFT of the conventional active matrix substrate of Comparative Embodiment 1.

FIG. 5 is a schematic cross-sectional view showing a conventional TFT including a semiconductor layer consisting of a-Si.

FIG. 6 is a schematic cross-sectional view showing a conventional auxiliary capacitance part.

FIG. 7 is a schematic cross-sectional view showing a modified example of the conventional auxiliary capacitance part.

### DESCRIPTION OF EMBODIMENTS

Preferable embodiments of the active matrix substrate of the present invention will be described below. The embodiments of the active matrix substrate of the present invention can appropriately be combined with each other.

The term “patterning” herein means, for example, a process including: applying a photosensitive resist to the whole surface of a substrate with a target layer or film deposited thereon; exposing the resist to light to form a resist pattern; removing the part of the target layer or film exposed through the resist pattern by etching; and then peeling the resist pattern off, thereby completing the target layer or film.

In one embodiment of the active matrix substrate of the present invention, the oxide semiconductor may consist of indium (In), gallium (Ga), zinc (Zn), and oxygen (O).

In the above embodiment, the semiconductor layer may consist of the oxide semiconductor In—Ga—Zn—O, for example. This semiconductor has a higher electron mobility than a-Si, and thus is suitable for rapidly driving circuits.

The oxide semiconductor may be an oxide semiconductor other than In—Ga—Zn—O, such as In-Tin-Zn—O consisting of indium (In), Tin (Tin), zinc (Zn), and oxygen (O), or In—Al—Zn—O consisting of indium (In), aluminum (Al), zinc (Zn), and oxygen (O).

In one embodiment of the active matrix substrate of the present invention, the spin-on-glass material may be a photosensitive material.

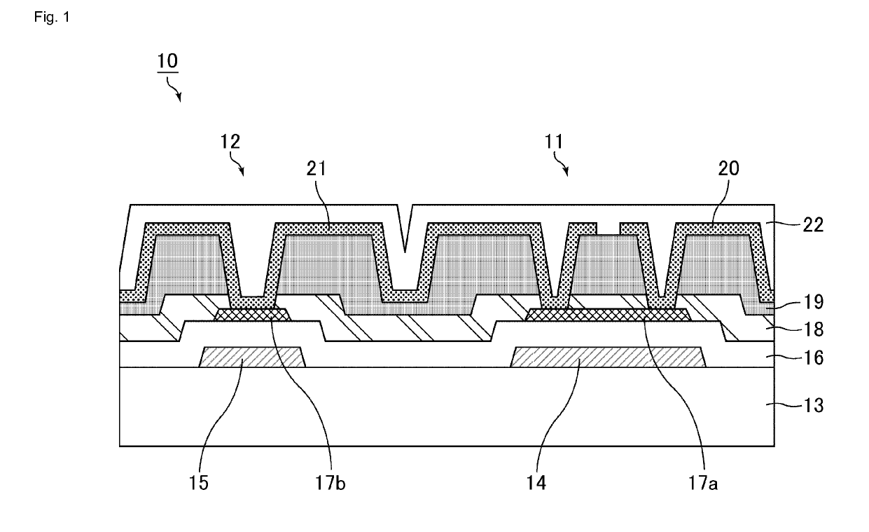

In the above embodiment, the photosensitive spin-on-glass material can be exposed to light. Thus, as will be mentioned later, the interlayer insulating film formed from the spin-on-glass material and the etching stopper layer formed from the insulation material can simultaneously be patterned (for example, as shown in FIG. 1, an interlayer insulating film 19 and an etching stopper layer 18 are simultaneously patterned so as to integrate the side wall of the interlayer insulating film 19 and the side wall of the etching stopper layer 18). This leads to a smaller number of photomasks in comparison with the production of a conventional active matrix substrate using a non-photosensitive spin-on-glass material to be mentioned later.

In one embodiment of the active matrix substrate of the present invention, the etching stopper layer may be in contact with at least part of the surface of the semiconductor layer opposite to the glass substrate.

In one embodiment of the active matrix substrate of the present invention, the surface of the interlayer insulating film facing the glass substrate may be in contact with at least part of the surface of the etching stopper layer opposite to the glass substrate.

In the above embodiment, the etching stopper layer and the interlayer insulating film are disposed between the semiconductor layer consisting of the oxide semiconductor and the passivation film. This ensures a sufficient distance between the semiconductor layer consisting of the oxide semiconductor and the passivation film. Specifically, the semiconductor layer consisting of the oxide semiconductor and the passivation film are disposed apart from each other by a distance corresponding to the sum of the thickness of the etching stopper layer and the thickness of the interlayer insulating film (for example, as shown in FIG. 1, a semiconductor layer 17a consisting of an oxide semiconductor and a passivation film 22 are disposed apart from each other by a distance corresponding to the sum of the thickness of the etching stopper layer 18 and the thickness of the interlayer insulating film 19). This sufficiently prevents the movement of hydrogen (H) in the passivation film to the oxide semiconductor and the resulting combination of the hydrogen and oxygen (O) in the oxide semiconductor, and also sufficiently prevents the conversion of the oxide semiconductor into a conductor. Thus, the present invention can provide an active matrix substrate including a thin film transistor which sufficiently achieves high reliability.

Further, in the above embodiment, the capacitance between wires (e.g., a capacitance between a gate line and a source line) can sufficiently be reduced. Specifically, for example, the etching stopper layer and the interlayer insulating film are disposed between the gate electrode and the source electrode. Thus, the gate electrode and the source electrode are sufficiently apart from each other (for example, as shown in FIG. 1, the etching stopper layer 18 and the interlayer insulating film 19 are disposed between a gate electrode 14 and a source electrode 20, so that the gate electrode 14 and the source electrode 20 are sufficiently apart from each other). This leads to a sufficiently low capacitance between wires. Thus, the present invention can provide an active matrix substrate including a thin film transistor which sufficiently achieves a low capacitance.

Therefore, as mentioned above, the present invention can provide an active matrix substrate including a thin film transistor which sufficiently achieves high reliability and a low capacitance.

In order to favorably achieve the effects of one embodiment of the present invention, the distance between the oxide semiconductor and the passivation film is preferably not smaller than 0.2 μm but not larger than 3.0 μm.

The etching stopper layer may have any thickness, and it is preferably not smaller than 0.05 μm but not larger than 0.2 μm in thickness.

The interlayer insulating film may have any thickness, and it is preferably not smaller than 1.5 μm but not larger than 2.5 μm in thickness.

The capacitance between wires is appropriately set in accordance with the size and the resolution of a liquid crystal panel to be driven.

The following will describe an auxiliary capacitance part of the active matrix substrate of the present invention. In general, the capacitance of the auxiliary capacitance part is preferably as high as possible.

FIG. 6 is a schematic cross-sectional view showing a conventional auxiliary capacitance part. In an auxiliary capacitance part 512 shown in FIG. 6, the capacitance between electrodes (the capacitance between an auxiliary capacitance electrode 515 and a drain electrode 521) is a value with a gate insulator 516 and an etching stopper layer 518 existing between the electrodes. The capacitance of the auxiliary capacitance part 512 may be increased by expanding the area in which the electrodes overlap. Such an expansion, however, decreases the aperture ratio of the liquid crystal panel.

The following will describe an auxiliary capacitance part 612 shown in FIG. 7 intended to increase the capacitance (the capacitance between electrodes) of the auxiliary capacitance part. FIG. 7 is a schematic cross-sectional view showing a modified example of the conventional auxiliary capacitance part. In FIG. 7, not only the etching stopper layer but also the gate insulator is removed to some extent. In the auxiliary capacitance part 612 shown in FIG. 7, the capacitance between electrodes (the capacitance between an auxiliary capacitance electrode 615 and a drain electrode 621) is a value with a gate insulator 616 existing between the electrodes. The capacitance of the auxiliary capacitance part 612 shown in FIG. 7 can be higher than the capacitance of the auxiliary capacitance part 512 shown in FIG. 6. However, this causes a wide variation in capacitance in the plane of the substrate.

In the auxiliary capacitance part of the active matrix substrate of the present invention, hydrogen (H) to be introduced during dry etching of the etching stopper layer to be mentioned later combines with oxygen (O) in the oxide semiconductor. This causes oxygen loss in the oxide semiconductor and the resulting conversion of the oxide semiconductor into a conductor (for example, in FIG. 1, hydrogen (H) introduced during dry etching of the etching stopper layer 18 combines with oxygen (O) in an oxide semiconductor 17b, thereby causing oxygen loss in the oxide semiconductor 17b and conversion of the oxide semiconductor 17b into a conductor). Thus, the semiconductor layer consisting of the oxide semiconductor is to be converted into a conductor, so that the capacitance between electrodes (for example, the capacitance between an auxiliary capacitance electrode 15 and a drain electrode 21 in FIG. 1) becomes equal to the capacitance in the active matrix substrate including a gate insulator (for example, a gate insulator 16 in FIG. 1) between electrodes. This means that the capacitance of an auxiliary capacitance part 12 shown in FIG. 1 can be higher than the capacitance of the auxiliary capacitance part 512 shown in FIG. 6, for example. Therefore, this embodiment of the active matrix substrate of the present invention is also suitable for increasing the capacitance of the auxiliary capacitance part.

With a 0.3-μm-thick gate insulator (e.g., silicon oxide (SiO₂)) and a 0.1-μm-thick etching stopper layer (e.g., silicon oxide (SiO₂)), for example, the capacitance (the capacitance equal to that with a gate insulator) of the auxiliary capacitance part can be made 25% higher than the capacitance (the capacitance with the gate insulator 516 and the etching stopper layer 518) of the conventional auxiliary capacitance part 512 shown in FIG. 6 by the aforementioned process of converting the oxide semiconductor (In—Ga—Zn—O) of the auxiliary capacitance part into a conductor. This means that, in order to achieve the same capacitance, the auxiliary capacitance part can be designed with a size 25% smaller than the conventional auxiliary capacitance part, which is advantageous in that the loss of the transmissivity due to the auxiliary capacitance part of a liquid crystal panel can be reduced by 25%. The process of converting the oxide semiconductor (In—Ga—Zn—O) into a conductor may include, for example, etching the etching stopper layer of the auxiliary capacitance part with etching gas (e.g., tetrafluoromethane (CF₄) or oxygen (O₂)); ashing treatment with oxygen (O₂) so as to make it easy to remove a photosensitive resist; and treatment of converting the oxide semiconductor (In—Ga—Zn—O) into a conductor with hydrogen gas for about five seconds after the ashing treatment. The gas for converting the oxide semiconductor (In—Ga—Zn—O) into a conductor may be any gas except for oxygen gas, and may be nitrogen gas or argon (Ar) gas. The capacitance of the auxiliary capacitance part can appropriately be set in accordance with the size and the resolution of the liquid crystal panel to be driven.

Preferable embodiments of the display device of the present invention may include the active matrix substrate of any of the above preferable embodiments of the present invention, a substrate facing the active matrix substrate, and a display element interposed between the substrates. The embodiments of the display device of the present invention can appropriately be combined with each other.

Next, preferable embodiments of the production method for an active matrix substrate of the present invention will be described below. The embodiments of the production method for an active matrix substrate of the present invention can appropriately be combined with each other.

In one embodiment of the production method for an active matrix substrate of the present invention, the oxide semiconductor may consist of indium (In), gallium (Ga), zinc (Zn), and oxygen (O).

In one embodiment of the production method for an active matrix substrate of the present invention, the spin-on-glass material may be a photosensitive material.

In the above embodiment, the photosensitive spin-on-glass material can be exposed to light. Thus, the interlayer insulating film formed from the spin-on-glass material and the etching stopper layer formed from the insulation material can simultaneously be patterned (for example, as shown in FIG. 1, the interlayer insulating film 19 and the etching stopper layer 18 are simultaneously patterned so as to integrate the side wall of the interlayer insulating film 19 and the side wall of the etching stopper layer 18). This leads to a smaller number of photomasks in comparison with the production of a conventional active matrix substrate using a non-photosensitive spin-on-glass material to be mentioned later.

In one embodiment of the production method for an active matrix substrate of the present invention, in the step of forming the etching stopper layer and the interlayer insulating film, the etching stopper layer may be formed so as to be in contact with at least part of the surface of the semiconductor layer opposite to the glass substrate.

Also, in one embodiment of the production method for an active matrix substrate of the present invention, in the step of forming the etching stopper layer and the interlayer insulating film, the interlayer insulating film may be formed such that the surface of the interlayer insulating film facing the glass substrate is in contact with at least part of the surface of the etching stopper layer opposite to the glass substrate.

In the above embodiment, the etching stopper layer and the interlayer insulating film are formed between the semiconductor layer consisting of the oxide semiconductor and the passivation film. This ensures a sufficient distance between the semiconductor layer consisting of the oxide semiconductor and the passivation film. Specifically, the semiconductor layer consisting of the oxide semiconductor and the passivation film are disposed apart from each other by a distance corresponding to the sum of the thickness of the etching stopper layer and the thickness of the interlayer insulating film (for example, as shown in FIG. 1, the semiconductor layer 17a consisting of an oxide semiconductor and the passivation film 22 are disposed apart from each other by a distance corresponding to the sum of the thickness of the etching stopper layer 18 and the thickness of the interlayer insulating film 19). This sufficiently prevents the movement of hydrogen (H) in the passivation film to the oxide semiconductor and the resulting combination of the hydrogen and oxygen (O) in the oxide semiconductor, and also sufficiently prevents the conversion of the oxide semiconductor into a conductor. Thus, the present invention can provide a production method for an active matrix substrate including a thin film transistor which sufficiently achieves high reliability.

Further, in the above embodiment, the capacitance between wires (e.g., a capacitance between a gate line and a source line) can sufficiently be reduced. Specifically, for example, the etching stopper layer and the interlayer insulating film are formed between the gate electrode and the source electrode. Thus, the gate electrode and the source electrode are sufficiently apart from each other (for example, as shown in FIG. 1, the etching stopper layer 18 and the interlayer insulating film 19 are formed between the gate electrode 14 and the source electrode 20, so that the gate electrode 14 and the source electrode 20 are sufficiently apart from each other). This leads to a sufficiently low capacitance between wires. Thus, the present invention can provide a production method for an active matrix substrate including a thin film transistor which sufficiently achieves a low capacitance.

Therefore, as mentioned above, the production method for an active matrix substrate of the present invention can provide a production method for an active matrix substrate including a thin film transistor which sufficiently achieves high reliability and a low capacitance without an increase in the number of photomasks.

Preferable embodiments of the active matrix substrate produced by the production method for an active matrix substrate of the present invention are similar to the aforementioned preferable embodiments of the active matrix substrate of the present invention.

Preferable embodiments of the production method for a display device of the present invention may include: producing an active matrix substrate by the production method for an active matrix substrate of any of the aforementioned preferable embodiments of the present invention; and interposing a display element between the active matrix substrate and a substrate facing the active matrix substrate. The embodiments of the production method for a display device of the present invention can appropriately be combined with each other.

Preferable embodiments of the display device produced by the production method for a display device of the present invention are similar to the aforementioned preferable embodiments of the display device of the present invention.

The aforementioned embodiments may appropriately be combined with each other within the spirit of the present invention.

The present invention will more specifically be described in the following embodiment referring to the drawings. Still, this embodiment is not intended to limit the present invention.

The basic components of the active matrix substrate typically include a TFT, an auxiliary capacitance part, and the like each disposed on a glass substrate which is an insulation substrate.

### Embodiment 1

An active matrix substrate 10 of Embodiment 1 will be described referring to FIG. 1. FIG. 1 is a schematic cross-sectional view of the active matrix substrate of Embodiment 1.

The basic components of the active matrix substrate 10 of Embodiment 1 are a TFT 11 and an auxiliary capacitance part 12 each disposed on a glass substrate 13.

In the active matrix substrate 10 of Embodiment 1, the TFT 11 includes: a gate electrode 14 disposed on the glass substrate 13; a gate insulator 16 covering the gate electrode 14; a semiconductor layer 17a which consists of an oxide semiconductor, which is disposed on the gate insulator 16, and which overlaps the gate electrode 14; an etching stopper layer 18 in contact with part of the surface of the semiconductor layer 17a opposite to the glass substrate 13; an interlayer insulating film 19 in contact with substantially the whole surface of the etching stopper layer 18 opposite to the glass substrate 13; a source electrode 20 and a drain electrode 21 of the TFT 11 each in contact with part of the semiconductor layer 17a; and a passivation film 22 covering the TFT 11.

In the active matrix substrate 10 of Embodiment 1, the auxiliary capacitance part 12 includes: an auxiliary capacitance electrode 15 disposed on the glass substrate 13; the gate insulator 16 covering the auxiliary capacitance electrode 15; a semiconductor layer 17b which consists of an oxide semiconductor, which is disposed on the gate insulator 16, and which overlaps the auxiliary capacitance electrode 15; the etching stopper layer 18 in contact with part of the surface of the semiconductor layer 17b opposite to the glass substrate 13; the interlayer insulating film 19 in contact with substantially the whole surface of the etching stopper layer 18 opposite to the glass substrate 13; the drain electrode 21 of the TFT 11 in contact with part of the semiconductor layer 17b; and the passivation film 22 covering the TFT 11.

In the active matrix substrate 10 of Embodiment 1, the oxide semiconductor of the semiconductor layer 17a is In—Ga—Zn—O consisting of indium (In), gallium (Ga), zinc (Zn), and oxygen (O). Such a semiconductor has a higher electron mobility than an a-Si semiconductor layer, and thus can achieve a rapidly driving circuit.

In the active matrix substrate 10 of Embodiment 1, the etching stopper layer 18 is formed from an insulation material. The insulation material may be SiO₂, for example.

In the active matrix substrate 10 of Embodiment 1, the interlayer insulating film 19 is formed from a photosensitive spin-on-glass material. The photosensitive spin-on-glass material may be a commercially available siloxane-based spin-on-glass material, for example. The photosensitive spin-on-glass material can be exposed to light, so that the interlayer insulating film 19 formed from the spin-on-glass material and the etching stopper layer 18 can simultaneously be patterned. Thus, as will be mentioned later, the production of the active matrix substrate 10 of Embodiment 1 uses one less photomask than the production of an active matrix substrate 210 of Comparative Embodiment 1.

Therefore, as mentioned above, Embodiment 1 can provide the active matrix substrate 10 including the etching stopper layer 18 and the interlayer insulating film 19 between the semiconductor layer 17a consisting of the oxide semiconductor (In—Ga—Zn—O) and the passivation film 22. This ensures a sufficient distance between the semiconductor layer 17a consisting of the oxide semiconductor (In—Ga—Zn—O) and the passivation film 22. Specifically, the semiconductor layer 17a consisting of the oxide semiconductor (In—Ga—Zn—O) and the passivation film 22 are disposed apart from each other by a distance corresponding to the sum of the thickness of the etching stopper layer 18 and the thickness of the interlayer insulating film 19. This sufficiently prevents the movement of hydrogen (H) in the passivation film 22 to the oxide semiconductor (In—Ga—Zn—O) and the resulting combination of the hydrogen and oxygen (O) in the oxide semiconductor (In—Ga—Zn—O), and also sufficiently prevents the conversion of the oxide semiconductor (In—Ga—Zn—O) into a conductor. Therefore, Embodiment 1 can provide the active matrix substrate 10 including the TFT 11 which sufficiently achieves high reliability.

Further, as mentioned above, Embodiment 1 can sufficiently reduce the capacitance between wires in the active matrix substrate 10. Specifically, for example, the etching stopper layer 18 and the interlayer insulating film 19 are disposed between the gate electrode 14 and the source electrode 20. Thus, the gate electrode 14 and the source electrode 20 are sufficiently apart from each other. This leads to a sufficiently low capacitance between wires. Therefore, Embodiment 1 can provide the active matrix substrate 10 including the TFT 11 which sufficiently achieves a low capacitance.

Therefore, as mentioned above, Embodiment 1 can provide the active matrix substrate 10 including the TFT 11 which sufficiently achieves high reliability and a low capacitance.

In the active matrix substrate 10 of Embodiment 1, the thickness of the etching stopper layer 18 is 0.1 μm, the thickness of the interlayer insulating film 19 is 2.0 μm, and the distance between the semiconductor layer 17a consisting of the oxide semiconductor (In—Ga—Zn—O) and the passivation film 22 is 2.1 μm.

In the auxiliary capacitance part 12 of the active matrix substrate 10 of Embodiment 1, hydrogen (H) to be introduced during dry etching of the etching stopper layer 18 to be mentioned later combines with oxygen (O) in the semiconductor layer 17b consisting of the oxide semiconductor (In—Ga—Zn—O). This causes oxygen loss in the oxide semiconductor (In—Ga—Zn—O) and the resulting conversion of the oxide semiconductor (In—Ga—Zn—O) into a conductor. Thus, the semiconductor layer 17b consisting of the oxide semiconductor (In—Ga—Zn—O) is to be converted into a conductor, so that the capacitance between electrodes (the capacitance between the auxiliary capacitance electrode 15 and the drain electrode 21) becomes equal to the capacitance in the active matrix substrate including the gate insulator 16 between the electrodes. As will be mentioned later, this is also suitable in that the capacitance of the auxiliary capacitance part 12 can be higher than the capacitance of an auxiliary capacitance part 212 of the active matrix substrate 210 of Comparative Embodiment 1. With a 0.3-μm-thick gate insulator 16 (e.g., silicon oxide (SiO₂)) and a 0.1-μm-thick etching stopper layer 18 (e.g., silicon oxide (SiO₂)), for example, the capacitance of the auxiliary capacitance part 12 (the capacitance equal to that with the gate insulator 16) can be made 25% higher than the capacitance (the capacitance with the gate insulator 516 and the etching stopper layer 518) of the conventional auxiliary capacitance part 512 shown in FIG. 6 by the aforementioned process of converting the semiconductor layer 17b consisting of the oxide semiconductor (In—Ga—Zn—O) of the auxiliary capacitance part 12 into a conductor. This means that, in order to achieve the same capacitance, the auxiliary capacitance part can be designed with a size 25% smaller than the conventional auxiliary capacitance part, which is advantageous in that the loss of the transmissivity due to the auxiliary capacitance part of a liquid crystal panel can be reduced by 25%. The process of converting the semiconductor layer 17b consisting of the oxide semiconductor (In—Ga—Zn—O) into a conductor may include, for example, etching the etching stopper layer 18 of the auxiliary capacitance part 12 with etching gas (e.g., tetrafluoromethane (CF₄) or oxygen (O₂)); ashing treatment with oxygen (O₂) so as to make it easy to remove a photosensitive resist; and treatment of converting the semiconductor layer 17b consisting of the oxide semiconductor (In—Ga—Zn—O) into a conductor with hydrogen gas for about five seconds after the ashing treatment. The gas for converting the semiconductor layer 17b consisting of the oxide semiconductor (In—Ga—Zn—O) into a conductor may be any gas except for oxygen gas, and may be nitrogen gas or argon (Ar) gas.

The active matrix substrate 10 of Embodiment 1 may be applied to any liquid crystal display modes. Examples of the mode include multi-domain vertical alignment (MVA), in-plane switching (IPS), fringe field switching (FFS), and transverse bend alignment (TBA). This active matrix substrate can also suitably be applied to the polymer sustained alignment (PSA) technique and the photo alignment technique. The pixels may have any shape. For example, they may be vertically long pixels, horizontally long pixels, pixels with a shape like the inequality sign, or pixels in a delta arrangement.

A display device of Embodiment 1 includes the aforementioned active matrix substrate 10 of Embodiment 1, a substrate facing the active matrix substrate 10, and a display element interposed between the substrates. One suitable display device of Embodiment 1 is a liquid crystal display device including the active matrix substrate 10, a color filter (CF) substrate facing the active matrix substrate 10, and a display element and a liquid crystal layer each interposed between the substrates.

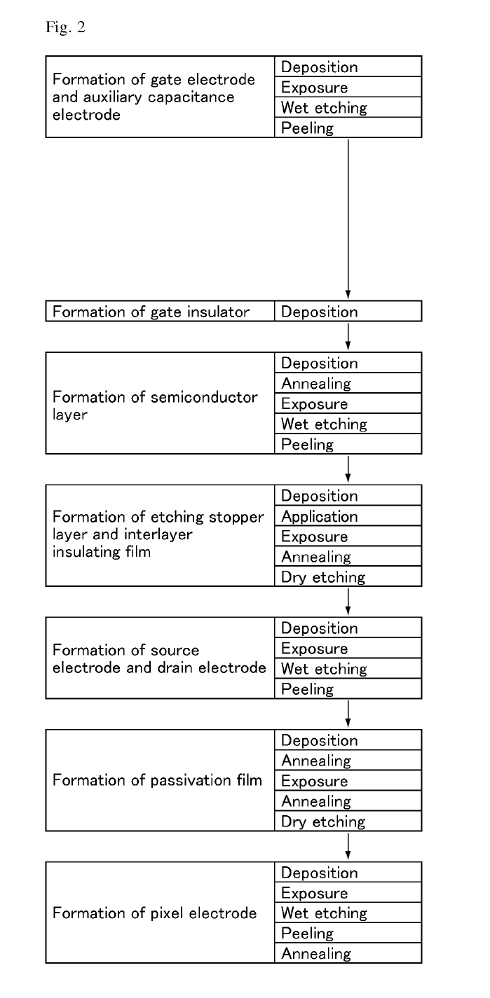

The following will describe a production method for the TFT 11 and the auxiliary capacitance part 12 of the active matrix substrate 10 of Embodiment 1 referring to FIG. 2. FIG. 2 is a process chart showing a production process of the TFT and the auxiliary capacitance part of the active matrix substrate of Embodiment 1. The production method for the active matrix substrate 10 of Embodiment 1 includes the steps of: forming a gate electrode and an auxiliary capacitance electrode; forming a gate insulator; forming a semiconductor layer; forming an etching stopper layer and an interlayer insulating film; forming a source electrode and a drain electrode; forming a passivation film; and forming a pixel electrode.

### (Step of Forming Gate Electrode and Auxiliary Capacitance Electrode)

Metal films of copper (Cu) and titanium (Ti), for example, are continually deposited on the whole surface of the glass substrate 13. A photosensitive resist is then applied to the whole surface of the substrate with the metal films of copper (Cu) and titanium (Ti) continually deposited thereon. The resist is then exposed to light, thereby forming a resist pattern. The metal films of copper (Cu) and titanium (Ti) exposed through the resist pattern are then removed by wet etching and the resist pattern is then peeled off, thereby forming a gate electrode 14 and an auxiliary capacitance electrode 15. The gate electrode 14 and the auxiliary capacitance electrode 15 are each about 0.5 μm thick.

### (Step of Forming Gate Insulator)

An insulation material of silicon oxide (SiO₂) or silicon nitride (SiNx), for example, is deposited on the whole surface of the substrate with the gate electrode 14 and the auxiliary capacitance electrode 15 formed thereon by the above step of forming a gate electrode and an auxiliary capacitance electrode, thereby forming a gate insulator 16. The gate insulator 16 is about 0.4 μm thick.

### (Step of Forming Semiconductor Layer)

An oxide semiconductor In—Ga—Zn—O is deposited on the whole surface of the substrate with the gate insulator 16 formed thereon by the above step of forming a gate insulator. The workpiece is then annealed in the air or nitrogen atmosphere, and a photosensitive resist is applied to the whole surface of the substrate with the oxide semiconductor In—Ga—Zn—O deposited thereon. The resist is then exposed to light, thereby forming a resist pattern. The In—Ga—Zn—O exposed through the resist pattern is removed by wet etching and the resist pattern is then peeled off, thereby forming a semiconductor layer 17a and a semiconductor layer 17b. The semiconductor layer 17a and the semiconductor layer 17b are each about 0.05 μm thick.

### (Step of Forming Etching Stopper Layer and Interlayer Insulating Film)

An insulation material of silicon oxide (SiO₂) is deposited using a film-forming device such as a chemical vapor deposition (CVD) device on the whole surface of the substrate with the semiconductor layer 17a and the semiconductor layer 17b formed thereon by the above step of forming a semiconductor layer. Before the deposition of the insulation material of silicon oxide (SiO₂), plasma treatment with nitrous oxide (N₂O) or oxygen (O₂), for example, may be performed. The plasma treatment can supply sufficient oxygen (O₂) to the oxide semiconductor In—Ga—Zn—O in which the oxygen (O₂) is easily separated by vacuum treatment or plasma treatment. Then, immediately after the plasma treatment, the insulation material of silicon oxide (SiO₂) is deposited on the oxide semiconductor In—Ga—Zn—O to protect the oxide semiconductor In—Ga—Zn—O. This results in stable transistor characteristics. Next, a photosensitive spin-on-glass material (e.g., a commercially available siloxane-based spin-on-glass material) is applied to the whole surface of the substrate with the insulation material of silicon oxide (SiO₂) deposited thereon. The spin-on-glass material is then exposed to light, thereby forming a pattern. The workpiece is annealed in the air or nitrogen atmosphere and the insulation material of silicon oxide (SiO₂) exposed through the pattern is removed by dry etching, thereby forming an etching stopper layer 18 formed from the insulation material and the interlayer insulating film 19 formed from the spin-on-glass material. The etching stopper layer 18 is about 0.1 μm thick and the interlayer insulating film 19 is about 2.0 μm thick. The annealing of the semiconductor layer in the previous step and the annealing of the spin-on-glass material in this step can simultaneously be performed so as to shorten the production process.

### (Step of Forming Source Electrode and Drain Electrode)

Metal films of copper (Cu) and titanium (Ti), for example, are continually deposited on the whole surface of the substrate with the etching stopper layer 18 and the interlayer insulating film 19 formed thereon by the above step of forming an etching stopper layer and an interlayer insulating film. Next, a photosensitive resist is applied to the whole surface of the substrate with the metal films of copper (Cu) and titanium (Ti) continually deposited thereon. The resist is then exposed to light, thereby forming a resist pattern. The metal films of copper (Cu) and titanium (Ti) exposed through the resist pattern are removed by wet etching and the resist pattern is then peeled off, thereby forming a source electrode 20 and a drain electrode 21. The source electrode 20 and the drain electrode 21 are each about 0.5 μm thick.

### (Step of Forming Passivation Film)

An insulation material of excellently moisture-proof silicon nitride (SiNx), for example, is deposited on the whole surface of the substrate with the source electrode 20 and the drain electrode 21 formed thereon by the above step of forming a source electrode and a drain electrode. Next, the workpiece is annealed in the air, and a photosensitive resist (e.g., an organic insulating film) is applied to the whole surface of the substrate with the insulation material of silicon nitride (SiNx) deposited thereon. The resist is then exposed to light, thereby forming a resist pattern. The workpiece is again annealed and the insulation material of silicon nitride (SiNx) exposed through the resist pattern is removed by dry etching, thereby forming a passivation film 22. The passivation film 22 is about 0.3 μm thick.

### (Step of Forming Pixel Electrode)

A transparent metal of indium tin oxide (ITO), for example, is deposited on the whole surface of the substrate with the passivation film 22 formed thereon by the above step of forming a passivation film. Next, a photosensitive resist is applied to the whole surface of the substrate with the transparent metal of indium tin oxide (ITO) deposited thereon. The resist is then exposed to light, thereby forming a resist pattern. The transparent metal of indium tin oxide (ITO) exposed through the resist pattern is removed by wet etching, the resist pattern is then peeled off, and the workpiece is annealed, thereby forming a pixel electrode (not shown). The pixel electrode is about 0.1 μm thick.

The aforementioned steps can provide the active matrix substrate 10 of Embodiment 1.

In the production method for the active matrix substrate 10 of Embodiment 1, the oxide semiconductor of the semiconductor layer 17a is In—Ga—Zn—O consisting of indium (In), gallium (Ga), zinc (Zn), and oxygen (O). Such a semiconductor layer has a higher electron mobility than a-Si semiconductor layers, and thus can achieve a rapidly driving circuit.

In the production method for the active matrix substrate 10 of Embodiment 1, the photosensitive spin-on-glass material can be exposed to light. Thus, the interlayer insulating film 19 formed from the spin-on-glass material and the etching stopper layer 18 can simultaneously be patterned. As shown in FIG. 2, the number of exposure steps is six in the production method for the active matrix substrate 10 of Embodiment 1, so that six photomasks are used. As will be mentioned later, the production of the active matrix substrate 10 of Embodiment 1 uses one less photomask than the production of the active matrix substrate 210 of Comparative Embodiment 1. With the photosensitive spin-on-glass material, the etching stopper layer 18 can be etched in the production method for the active matrix substrate 10 of Embodiment 1. With a non-photosensitive spin-on-glass material, in contrast, the etching stopper layer 18 and the interlayer insulating film 19 need to be etched. Thus, the use of a photosensitive spin-on-glass material can shorten the etching time in comparison with the use of a non-photosensitive spin-on-glass material.

As mentioned above, in the production method for the active matrix substrate 10 of Embodiment 1, the etching stopper layer 18 and the interlayer insulating film 19 are formed between the semiconductor layer 17a consisting of the oxide semiconductor (In—Ga—Zn—O) and the passivation film 22. This ensures a sufficient distance between the semiconductor layer 17a consisting of the oxide semiconductor (In—Ga—Zn—O) and the passivation film 22. Specifically, the semiconductor layer 17a consisting of the oxide semiconductor (In—Ga—Zn—O) and the passivation film 22 are disposed apart from each other by a distance corresponding to the sum of the thickness of the etching stopper layer 18 and the thickness of the interlayer insulating film 19. This sufficiently prevents the movement of hydrogen (H) in the passivation film 22 to the oxide semiconductor (In—Ga—Zn—O) and the resulting combination of the hydrogen and oxygen (O) in the oxide semiconductor (In—Ga—Zn—O), and also sufficiently prevents the conversion of the oxide semiconductor (In—Ga—Zn—O) into a conductor. Therefore, Embodiment 1 can provide a production method for the active matrix substrate 10 including the TFT 11 which sufficiently achieves high reliability.

Further, as mentioned above, Embodiment 1 can sufficiently reduce the capacitance between wires in the production method for the active matrix substrate 10. Specifically, for example, the etching stopper layer 18 and the interlayer insulating film 19 are formed between the gate electrode 14 and the source electrode 20. Thus, the gate electrode 14 and the source electrode 20 are sufficiently apart from each other. This leads to a sufficiently low capacitance between wires. Therefore, Embodiment 1 can provide a production method for the active matrix substrate 10 including the TFT 11 which sufficiently achieves a low capacitance.

Therefore, as mentioned above, Embodiment 1 can provide the production method for the active matrix substrate 10 including the TFT 11 which sufficiently achieves high reliability and a low capacitance without an increase in the number of photomasks.

In the production method for the active matrix substrate 10 of Embodiment 1, the distance between the semiconductor layer 17a consisting of the oxide semiconductor (In—Ga—Zn—O) and the passivation film 22 is 2.1 μm.

A production method for a display device of Embodiment 1 includes: producing the active matrix substrate 10 by the aforementioned production method for the active matrix substrate 10 of Embodiment 1; and interposing a display element between the active matrix substrate 10 and a substrate facing the active matrix substrate 10. One suitable production method for display device of Embodiment 1 is a production method for a liquid crystal display device including: producing the active matrix substrate 10 by the production method for the active matrix substrate 10; and interposing a display element and a liquid crystal layer between the active matrix substrate 10 and a CF substrate facing the active matrix substrate 10.

### Comparative Embodiment 1

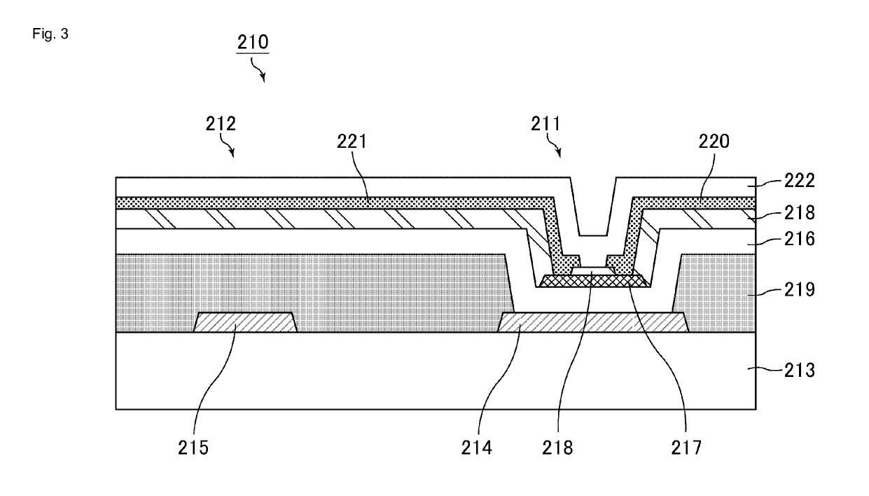

The active matrix substrate 210 of Comparative Embodiment 1 will be described referring to FIG. 3. FIG. 3 is a schematic cross-sectional view of the conventional active matrix substrate of Comparative Embodiment 1.

The basic components of the active matrix substrate 210 of Comparative Embodiment 1 are a TFT 211 and the auxiliary capacitance part 212 each disposed on a glass substrate 213.

In the active matrix substrate 210 of Comparative Embodiment 1, the TFT 211 includes: a gate electrode 214 disposed on the glass substrate 213; the interlayer insulating film 219 in contact with part of the gate electrode 214; a gate insulator 216 covering the gate electrode 214 and the interlayer insulating film 219; the semiconductor layer 217 which consists of an oxide semiconductor, which is disposed on the gate insulator 216, and which overlaps the gate electrode 214; an etching stopper layer 218 in contact with part of the surface of the semiconductor layer 217 opposite to the glass substrate 213; a source electrode 220 and a drain electrode 221 of the TFT 211 each in contact with part of the semiconductor layer 217; and the passivation film 222 covering the TFT 211.

In the active matrix substrate 210 of Comparative Embodiment 1, the auxiliary capacitance part 212 includes: an auxiliary capacitance electrode 215 disposed on the glass substrate 213; the interlayer insulating film 219 covering the auxiliary capacitance electrode 215; the gate insulator 216 covering the interlayer insulating film 219; the etching stopper layer 218 covering the gate insulator 216; the drain electrode 221 covering the etching stopper layer 218; and the passivation film 222.

In the active matrix substrate 210 of Comparative Embodiment 1, the oxide semiconductor of the semiconductor layer 217 is In—Ga—Zn—O consisting of indium (In), gallium (Ga), zinc (Zn), and oxygen (O).

In the active matrix substrate 210 of Comparative Embodiment 1, the etching stopper layer 218 is formed from an insulation material. The insulation material may be SiO₂, for example.

In the active matrix substrate 210 of Comparative Embodiment 1, the interlayer insulating film 219 is formed from a non-photosensitive spin-on-glass material. Patterning of the non-photosensitive spin-on-glass material requires additional steps of applying a photosensitive resist and exposing the resist to light, for example. Thus, as will be mentioned later, the production of the active matrix substrate 210 of Comparative Embodiment 1 uses one more photomask than the production of the active matrix substrate 10 of Embodiment 1.

Thus, in the above active matrix substrate 210 of Comparative Embodiment 1, only the etching stopper layer 218 is disposed between the semiconductor layer 217 consisting of the oxide semiconductor (In—Ga—Zn—O) and the passivation film 222. This fails to ensure a sufficient distance between the semiconductor layer 217 consisting of the oxide semiconductor (In—Ga—Zn—O) and the passivation film 222. Specifically, the semiconductor layer 217 consisting of the oxide semiconductor (In—Ga—Zn—O) and the passivation film 222 are disposed apart from each other by a distance corresponding to the thickness of the etching stopper layer 218. This fails to sufficiently prevent the movement of hydrogen (H) in the passivation film 222 to the oxide semiconductor (In—Ga—Zn—O) and the resulting combination of the hydrogen and oxygen (O) in the oxide semiconductor (In—Ga—Zn—O), and also fails to sufficiently prevent the conversion of the oxide semiconductor (In—Ga—Zn—O) into a conductor.

Further, as mentioned above, the active matrix substrate 210 of Comparative Embodiment 1 fails to give a sufficiently low capacitance between wires. Specifically, for example, the gate insulator 216 is disposed between the gate electrode 214 and the source electrode 220, so that the gate electrode 214 and the source electrode 220 fail to sufficiently be apart from each other. This fails to give a sufficiently low capacitance between wires.

In the active matrix substrate 210 of Comparative Embodiment 1, the etching stopper layer 218 is 0.1 μm thick, the gate insulator 216 is 0.3 μm thick, and the distance between the semiconductor layer 217 consisting of the oxide semiconductor (In—Ga—Zn—O) and the passivation film 222 is 0.1 μm.

In the auxiliary capacitance part 212 of the active matrix substrate 210 of Comparative Embodiment 1, the capacitance between the electrodes (the capacitance between the auxiliary capacitance electrode 215 and the drain electrode 221) is the capacitance with the interlayer insulating film 219, the gate insulator 216, and the etching stopper layer 218 existing between the electrodes. Thus, the capacitance of the auxiliary capacitance part 212 cannot be higher than the capacitance of the auxiliary capacitance part 12 of the active matrix substrate 10 of Embodiment 1.

A display device of Comparative Embodiment 1 includes the aforementioned active matrix substrate 210 of Comparative Embodiment 1, a substrate facing the active matrix substrate 210, and a display element interposed between the substrates. One display device of Comparative Embodiment 1 is a liquid crystal display device including the active matrix substrate 210, a color filter (CF) substrate facing the active matrix substrate 210, and a display element and a liquid crystal layer each interposed between the substrates.

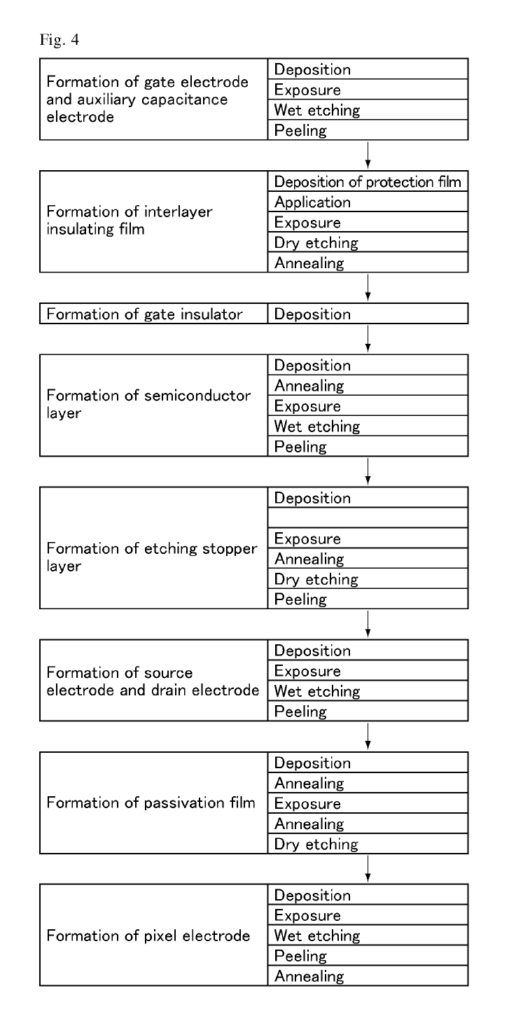

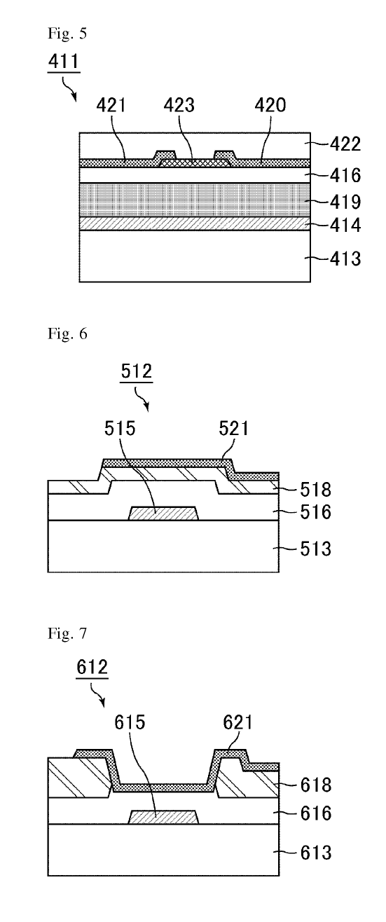

The following will describe a production method for the TFT 211 of the active matrix substrate 210 of Comparative Embodiment 1 referring to FIG. 4. FIG. 4 is a process chart showing a production process of the TFT of the conventional active matrix substrate of Comparative Embodiment 1. The production method for the active matrix substrate 210 of Comparative Embodiment 1 includes the steps of: forming a gate electrode and an auxiliary capacitance electrode; forming an interlayer insulating film; forming a gate insulator; forming a semiconductor layer; forming an etching stopper layer; forming a source electrode and a drain electrode; forming a passivation film; and forming a pixel electrode.

### (Step of Forming Gate Electrode and Auxiliary Capacitance Electrode)

Metal films of copper (Cu) and titanium (Ti), for example, are continually deposited on the whole surface of the glass substrate 213. A photosensitive resist is then applied to the whole surface of the substrate with the metal films of copper (Cu) and titanium (Ti) continually deposited thereon. The resist is then exposed to light, thereby forming a resist pattern. The metal films of copper (Cu) and titanium (Ti) exposed through the resist pattern are then removed by wet etching and the resist pattern is then peeled off, thereby forming a gate electrode 214 and an auxiliary capacitance electrode 215. The gate electrode 214 and the auxiliary capacitance electrode 215 are each about 0.5 μm thick.

### (Step of Forming Interlayer Insulating Film)

A protection film (e.g., silicon nitride (SiNx)) for protecting the gate electrode 214 and the auxiliary capacitance electrode 215 is deposited on the whole surface of the substrate with the gate electrode 214 and the auxiliary capacitance electrode 215 formed thereon by the above step of forming a gate electrode and an auxiliary capacitance electrode, and then a non-photosensitive spin-on-glass material is applied thereto. Next, a photosensitive resist is applied to the whole surface of the substrate with the non-photosensitive spin-on-glass material applied thereto. The resist is then exposed to light, thereby forming a resist pattern. The spin-on-glass material exposed through the resist pattern is then removed by dry etching and the workpiece is annealed in the air or nitrogen atmosphere, thereby forming an interlayer insulating film 219. In the step of forming a gate insulator to be mentioned later, the gas desorbed only from the hardened portion of the spin-on-glass material may have an influence on the transistor characteristics. Thus, the annealing is preferably performed at a temperature as high as 350° C. or higher. This makes it difficult to use a photosensitive resist in Comparative Embodiment 1. The interlayer insulating film 219 is about 2.0 μm thick.

### (Step of Forming Gate Insulator)

An insulation material of silicon oxide (SiO₂) or silicon nitride (SiNx) is deposited using a film-forming device such as a CVD device on the whole surface of the substrate with the interlayer insulating film 219 formed thereon by the above step of forming an interlayer insulating film, thereby forming a gate insulator 216. The gate insulator 216 is about 0.4 μm thick.

### (Step of Forming Semiconductor Layer)

An oxide semiconductor In—Ga—Zn—O is deposited on the whole surface of the substrate with the gate insulator 216 formed thereon by the above step of forming a gate insulator. Next, the workpiece is annealed in the air or nitrogen atmosphere and a photosensitive resist is applied to the whole surface of the substrate with the oxide semiconductor In—Ga—Zn—O deposited thereon. The resist is then exposed to light, thereby forming a resist pattern. The In—Ga—Zn—O exposed through the resist pattern is removed by wet etching and the resist pattern is then peeled off, thereby forming a semiconductor layer 217. The semiconductor layer 217 is about 0.05 μm thick.

### (Step of Forming Etching Stopper Layer)

An insulation material of silicon oxide (SiO₂), for example, is deposited on the whole surface of the substrate with the semiconductor layer 217 formed thereon by the above step of forming a semiconductor layer. Next, a photosensitive resist is applied to the whole surface of the substrate with the insulation material of silicon oxide (SiO₂) deposited thereon. The resist is then exposed to light, thereby forming a resist pattern. The workpiece is annealed using nitrogen (N₂), the insulation material of silicon oxide (SiO₂) exposed through the resist pattern is removed by dry etching, and the resist pattern is then peeled off, thereby forming an etching stopper layer 218 formed from the insulation material. The etching stopper layer 218 is about 0.1 μm thick.

### (Step of Forming Source Electrode and Drain Electrode)

Metal films of copper (Cu) and titanium (Ti), for example, are continually deposited on the whole surface of the substrate with the etching stopper layer 218 formed thereon by the above step of forming an etching stopper layer. Next, a photosensitive resist is applied to the whole surface of the substrate with the metal films of copper (Cu) and titanium (Ti) continually deposited thereon. The resist is then exposed to light, thereby forming a resist pattern. The metal films of copper (Cu) and titanium (Ti) exposed through the resist pattern are removed by wet etching and the resist pattern is then peeled off, thereby forming a source electrode 220 and a drain electrode 221. The source electrode 220 and the drain electrode 221 are each about 0.5 μm thick.

### (Step of Forming Passivation Film)

An insulation material of excellently moisture-proof silicon nitride (SiNx), for example, is deposited on the whole surface of the substrate with the source electrode 220 and the drain electrode 221 formed thereon by the above step of forming a source electrode and a drain electrode. Next, the workpiece is annealed in the air and a photosensitive resist (e.g., an organic insulating film) is applied to the whole surface of the substrate with the insulation material of silicon nitride (SiNx) deposited thereon. The resist is then exposed to light, thereby forming a resist pattern. The workpiece is again annealed and the insulation material of silicon nitride (SiNx) exposed through the resist pattern is removed by dry etching, thereby forming a passivation film 222. The passivation film 222 is about 0.3 μm thick.

### (Step of Forming Pixel Electrode)

A transparent metal of indium tin oxide (ITO), for example, is deposited on the whole surface of the substrate with the passivation film 222 formed thereon by the above step of forming a passivation film. Next, a photosensitive resist is applied to the whole surface of the substrate with the transparent metal of indium tin oxide (ITO) deposited thereon. The resist is then exposed to light, thereby forming a resist pattern. The transparent metal of indium tin oxide (ITO) exposed through the resist pattern is removed by wet etching, the resist pattern is then peeled off, and the workpiece is annealed, thereby forming a pixel electrode (not shown). The pixel electrode is about 0.1 μm thick.

As a result, the aforementioned active matrix substrate 210 of Comparative Embodiment 1 can be produced.

As shown in FIG. 4, the production method for the active matrix substrate 210 of Comparative Embodiment 1 includes seven exposure steps, so that seven photomasks are used. Thus, the production of the active matrix substrate 210 of Comparative Embodiment 1 uses one more photomask than the production of the active matrix substrate 10 of Embodiment 1.

As mentioned above, in the production method for the active matrix substrate 210 of Comparative Embodiment 1, only the etching stopper layer 218 is formed between the semiconductor layer 217 consisting of the oxide semiconductor (In—Ga—Zn—O) and the passivation film 222. This fails to ensure a sufficient distance between the semiconductor layer 217 consisting of the oxide semiconductor (In—Ga—Zn—O) and the passivation film 222. Specifically, the semiconductor layer 217 consisting of the oxide semiconductor (In—Ga—Zn—O) and the passivation film 222 are disposed apart from each other by a distance corresponding to the thickness of the etching stopper layer 218. This fails to sufficiently prevent the movement of hydrogen (H) in the passivation film 222 to the oxide semiconductor (In—Ga—Zn—O) and the resulting combination of the hydrogen and oxygen (O) in the oxide semiconductor (In—Ga—Zn—O), and also fails to sufficiently prevent the conversion of the oxide semiconductor (In—Ga—Zn—O) into a conductor.

Further, the aforementioned active matrix substrate 210 of Comparative Embodiment 1 fails to give a sufficiently low capacitance between wires. Specifically, for example, the gate insulator 216 is formed between the gate electrode 214 and the source electrode 220, so that the gate electrode 214 and the source electrode 220 fail to sufficiently be apart from each other. This fails to give a sufficiently low capacitance between wires.

In the active matrix substrate 210 of Comparative Embodiment 1, the etching stopper layer 218 is 0.1 μm thick, the gate insulator 216 is 0.3 μm thick, and the distance between the semiconductor layer 217 consisting of the oxide semiconductor (In—Ga—Zn—O) and the passivation film 222 is 0.1 μm.

A production method for a display device of Comparative Embodiment 1 includes: producing the active matrix substrate 210 by the aforementioned production method for the active matrix substrate 210 of Comparative Embodiment 1; and interposing a display element between the active matrix substrate 210 and a substrate facing the active matrix substrate 210. One production method for the display device of Comparative Embodiment 1 is a production method for a liquid crystal display device including: producing the active matrix substrate 210 by the production method for the active matrix substrate 210; and interposing a display element and a liquid crystal layer between the active matrix substrate 210 and a CF substrate facing the active matrix substrate 210.

### Other Preferable Embodiments

In embodiments of the present invention, organic electroluminescent display devices may also suitably be used instead of liquid crystal display devices.

In the active matrix substrate 10 of Embodiment 1, the oxide semiconductor is In—Ga—Zn—O. For example, the oxide semiconductor may be an oxide semiconductor other than In—Ga—Zn—O, such as In-Tin-Zn-O consisting of indium (In), Tin (Tin), zinc (Zn), and oxygen (O) or In—Al—Zn—O consisting of indium (In), aluminum (Al), zinc (Zn), and oxygen (O).

### REFERENCE SIGNS LIST

10, 210: active matrix substrate
11, 211, 411: TFT
12, 212, 512, 612: auxiliary capacitance part
13, 213, 413, 513, 613: glass substrate
14, 214, 414: gate electrode
15, 215, 515, 615: auxiliary capacitance electrode
16, 216, 416, 516, 616: gate insulator
17a, 17b, 217: semiconductor layer (oxide semiconductor)
18, 218, 518, 618: etching stopper layer
19, 219, 419: interlayer insulating film
20, 220, 420: source electrode
21, 221, 421, 521, 621: drain electrode
22, 222, 422: passivation film
423: semiconductor layer (a-Si)

1. An active matrix substrate comprising a thin film transistor that includes a semiconductor layer consisting of an oxide semiconductor,
the active matrix substrate comprising:
a glass substrate;
a gate electrode and an auxiliary capacitance electrode each disposed on the glass substrate;
a gate insulator covering the gate electrode and the auxiliary capacitance electrode;
the semiconductor layer consisting of the oxide semiconductor, the semiconductor layer including, on the gate insulator, a portion overlapping at least part of the gate electrode and a portion overlapping at least part of the auxiliary capacitance electrode;
an etching stopper layer;
an interlayer insulating film formed from a spin-on-glass material;
a source electrode and a drain electrode of the thin film transistor, the source and drain electrodes each being in contact with at least part of the semiconductor layer; and
a passivation film covering the thin film transistor,
the etching stopper layer covering at least part of the semiconductor layer in the plan view of the principal surface of the substrate, and
the interlayer insulating film covering at least part of the etching stopper layer in the plan view of the principal surface of the substrate.

2. The active matrix substrate according to claim 1,
wherein the oxide semiconductor consists of indium, gallium, zinc, and oxygen.

3. The active matrix substrate according to claim 1,
wherein the spin-on-glass material is a photosensitive material.

4. The active matrix substrate according to claim 1,
wherein the etching stopper layer is in contact with at least part of the surface of the semiconductor layer opposite to the glass substrate.

5. The active matrix substrate according to claim 1,
wherein the surface of the interlayer insulating film facing the glass substrate is in contact with at least part of the surface of the etching stopper layer opposite to the glass substrate.

6. A display device comprising
the active matrix substrate according to claim 1,
a substrate facing the active matrix substrate, and
a display element interposed between the substrates.

7. A production method for an active matrix substrate comprising a thin film transistor that includes a semiconductor layer consisting of an oxide semiconductor, the production method comprising the steps of:
forming a gate electrode and an auxiliary capacitance electrode on a glass substrate;
forming a gate insulator so as to cover the gate electrode and the auxiliary capacitance electrode;
forming the semiconductor layer that consists of the oxide semiconductor, on the gate insulator, so as to overlap at least part of the gate electrode and at least part of the auxiliary capacitance electrode;
depositing an insulation material and a spin-on-glass material;
forming an etching stopper layer formed from the insulation material and an interlayer insulating film formed from the spin-on-glass material by patterning the insulation material and the spin-on-glass material;
forming a source electrode and a drain electrode of the thin film transistor so as to be in contact with at least part of the semiconductor layer; and
forming a passivation film so as to cover the thin film transistor,
in the step of forming the etching stopper layer and the interlayer insulating film, the etching stopper layer being formed so as to cover at least part of the surface of the semiconductor layer opposite to the substrate in the plan view of the principal surface of the substrate, and
the interlayer insulating film being formed so as to cover at least part of the surface of the etching stopper layer opposite to the substrate in the plan view of the principal surface of the substrate.

8. The production method for an active matrix substrate according to claim 7,
wherein the oxide semiconductor consists of indium, gallium, zinc, and oxygen.

9. The production method for an active matrix substrate according to claim 7,
wherein the spin-on-glass material is a photosensitive material.

10. The production method for an active matrix substrate according to claim 7,
wherein, in the step of forming the etching stopper layer and the interlayer insulating film, the etching stopper layer is formed so as to be in contact with at least part of the surface of the semiconductor layer opposite to the glass substrate.

11. The production method for an active matrix substrate according to claim 7,
wherein, in the step of forming the etching stopper layer and the interlayer insulating film, the interlayer insulating film is formed such that the surface of the interlayer insulating film facing the glass substrate is in contact with at least part of the surface of the etching stopper layer opposite to the glass substrate.

12. A production method for a display device, comprising:
producing an active matrix substrate by the production method according to claim 7; and
interposing a display element between the active matrix substrate and a substrate facing the active matrix substrate.
